(19) United States
(12) Patent Application Publication
(10) Pub. No.: US 2004/0256687 A1
(43) Pub. Date: Dec. 23, 2004

(54) Optical module, method of manufacturing the same, and electronic instrument

(75) Inventor: Osamu Omori, Fujimi-machi (JP)

Correspondence Address: OLIFF & BERRIDGE, PLC, P.O. BOX 19928, ALEXANDRIA, VA, 22320, US

(73) Assignee: SEIKO EPSON CORPORATION, TOKYO (JP)

(21) Appl. No.: 10/766,935

(22) Filed: Jan. 30, 2004

(30) Foreign Application Priority Data
Feb. 7, 2003 (JP) 2003-030949

(51) Int. Cl. H01L 31/0203

(52) U.S. Cl. 257/433

(57) ABSTRACT

An optical module includes an interconnect board which has a base board and an interconnecting pattern formed on the base board; an optical chip which has an optical section and an electrode which electrically connects the optical section and the interconnecting pattern; and a body material which holds a lens which concentrates light on the optical section. The body material is directly attached to the optical chip.

Japanese Patent Application No. 2003-30949 filed on Feb. 7, 2003, is hereby incorporated by reference in its entirety.

### BACKGROUND OF THE INVENTION

The present invention relates to an optical module, a method of manufacturing the same, and an electronic instrument.

As a structure of an imaging optical module such as a CCD or CMOS sensor, a structure in which an optical chip is mounted on an interconnect board and a frame having a lens is mounted on the interconnect board has been known. Since the frame is attached based on the surface of the interconnect board as a reference, there may be a case where the frame is attached in a state in which the lens is inclined with respect to an optical section of the optical chip. In the case where the interconnect board is warped due to heat during the mounting step, the optical axes of the optical section and the lens are displaced, whereby reliability of the optical module is impaired.

### BRIEF SUMMARY OF THE INVENTION

An optical module according to one aspect of the present invention includes:

an interconnect board which includes a base board and an interconnecting pattern formed on the base board;

an optical chip which includes an optical section and an electrode which electrically connects the optical section and the interconnecting pattern; and

a body material which holds a lens which concentrates light on the optical section,

wherein the body material is directly attached to the optical chip.

An electronic instrument according to another aspect of the present invention has the above optical module.

A method of manufacturing an optical module according to a further aspect of the present invention includes:

mounting an optical chip which includes an optical section and an electrode on an interconnect board which includes a base board and an interconnecting pattern formed on the base board so that the electrode is electrically connected with the interconnecting pattern; and

directly attaching a body material which holds a lens which concentrates light on the optical section to the optical chip.

### BRIEF DESCRIPTION OF THE SEVERAL VIEWS OF THE DRAWING

FIG. 1 shows an optical module according to a first embodiment of the present invention.

FIG. 2 shows an optical chip according to the first embodiment of the present invention.

FIG. 3 shows an optical module according to a second embodiment of the present invention.

FIG. 4 shows an optical chip according to the second embodiment of the present invention.

FIG. 5 shows an optical module according to a modification of the second embodiment of the present invention.

FIG. 6 shows an optical module according to another modification of the second embodiment of the present invention.

FIG. 7 shows an optical module according to a third embodiment of the present invention.

FIG. 8 shows an optical module according to a modification of the third embodiment of the present invention.

FIG. 9 shows an optical module according to another modification of the third embodiment of the present invention.

FIG. 10 shows an electronic instrument according to an embodiment of the present invention.

FIG. 11 shows another electronic instrument according to an embodiment of the present invention.

FIGS. 12A and 12B show yet another electronic instrument according to an embodiment of the present invention.

### DETAILED DESCRIPTION OF THE EMBODIMENT

Embodiments of the present invention may allow the optical axes of an optical section and a lens to coincide accurately.

(1) An optical module according to one embodiment of the present invention includes:

an interconnect board which includes a base board and an interconnecting pattern formed on the base board;

an optical chip which includes an optical section and an electrode which electrically connects the optical section and the interconnecting pattern; and

a body material which holds a lens which concentrates light on the optical section,

wherein the body material is directly attached to the optical chip.

In this embodiment, the body material is directly attached to the optical chip. This enables the optical chip to mount on the body material in a flat manner, whereby the optical axes of the optical section and the lens can be allowed to coincide accurately. Therefore, an optical module having high reliability and high quality (high image quality, for example) can be provided.

(2) With this optical module,

an opening may be formed in the base board,

the optical chip may be bonded face down to the interconnect board so that the optical section faces the opening, and

the body material may be attached to the optical chip through the opening.

The size of the optical module can be reduced, since the body material is attached inside the opening and the thickness of the interconnect board does not affect the size of the optical module.

(3) With this optical module, the body material may be attached to a surface of the optical chip on which the optical section is formed.

(4) This optical module may further include a resin section which is provided between the body material and the interconnect board to bond the body material to the interconnect board.

This enables the body material and the interconnect board to be secured relative to each other.

(5) With this optical module,

the optical chip may be bonded face up to the interconnect board,

the electrode and the interconnecting pattern may be electrically connected through a wire, and

the resin section may seal at least the wire.

(6) With this optical module,

a space having a shape which surrounds the wire, and a hole which has a width smaller than a width of the space and opens to an outside from the space may be formed in the body material, and

the space may be filled with the resin section.

This facilitates the step of forming the resin section, the body material can be fixed with the interconnect board and sealing of the wire can be easily performed.

(7) With this optical module, the body material may be attached to the optical chip in a region except the optical section.

(8) With this optical module, the optical chip may further include a cover provided to cover the optical section, and the body material may be attached to the cover. This feature may prevent refuse or an adhesive material from entering the optical section.

(9) With this optical module,

the cover may include a plate section disposed above the optical section, and a spacer section which supports the plate section,

the spacer section may be attached to the optical chip, and

the body material may be attached to the plate section.

(10) With this optical module, the body material may be bonded to the optical chip through an adhesive sheet material. Since the sheet material has a predetermined shape, flatness of the body material may be rarely impaired.

(11) With this optical module, the body material may be bonded to the optical chip through an adhesive.

(12) An electronic instrument according to another aspect of the present invention has the above optical module.

(13) A method of manufacturing an optical module according to a further aspect of the present invention includes:

mounting an optical chip which includes an optical section and an electrode on an interconnect board which includes a base board and an interconnecting pattern formed on the base board so that the electrode is electrically connected with the interconnecting pattern; and

directly attaching a body material which holds a lens which concentrates light on the optical section to the optical chip.

In this embodiment, the body material is directly attached to the optical chip. This enables the optical chip to mount on the body material in a flat manner, whereby the optical axes of the optical section and the lens can be allowed to coincide accurately. Therefore, an optical module having high reliability and high quality (high image quality, for example) can be manufactured.

The embodiments of the present invention are described below with reference to the drawings.

### First Embodiment

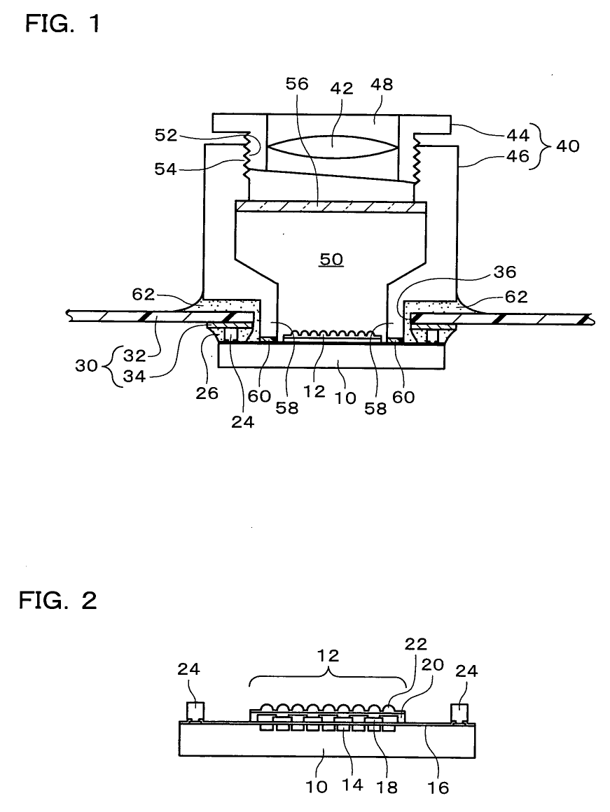

FIGS. 1 and 2 are views illustrating an optical module and a method of manufacturing the same according to a first embodiment of the present invention. FIG. 1 is a cross-sectional view of an optical module, and FIG. 2 is a cross-sectional view of an optical chip. An optical module according to the present embodiment includes an optical chip 10, an interconnect board 30, and a body material 40.

The optical chip 10 is generally in the shape of a rectangular parallelepiped. The optical chip 10 may be a semiconductor chip. As shown in FIG. 2, the optical chip 10 includes an optical section 12. The optical section 12 is a section upon which light is incident or from which light is emitted. The optical section 12 converts optical energy into another type of energy (electricity, for example). Specifically, the optical section 12 includes a plurality of energy conversion device 14 (light receiving device and light emitting device). In the present embodiment, the optical section 12 is a light receiving section. In this case, the optical chip 10 is a light receiving chip (imaging chip, for example). The energy conversion devices 14 (light receiving devices or image sensor devices) are arranged two-dimensionally and capable of sensing an image. Specifically, in the present embodiment, the optical module is an image sensor (CCD or CMOS sensor, for example). The energy conversion devices 14 are covered with a passivation film 16. The passivation film 16 has optical transparency. In the case of manufacturing the optical chip 10 by using a semiconductor base board (semiconductor wafer, for example), the passivation film 16 may be formed of a silicon oxide film or a silicon nitride film.

The optical section 12 may have a color filter 18. The color filter 18 is formed on the passivation film 16. A planarization layer 20 may be formed on the color filter 18, and a microlens array 22 may be formed on the planarization layer 20.

An electrode 24 (a plurality of electrodes 24 in many cases) is formed on the optical chip 10. The electrode 24 is electrically connected with the optical section 12. The electrode 24 includes a bump formed on a pad. The electrode 24 may be formed merely of the pad. The electrode 24 is formed outside the optical section 12. The optical section 12 and the electrode 24 may be formed on a single surface of the optical chip 10. In more detail, the optical section 12 may be formed at the center of one surface of the optical chip 10, and the electrode 24 may be formed on the end of the surface of the optical chip 10. In the case where the optical chip 10 is in the shape of a polygon (quadrilateral, for example), the electrodes 24 may be disposed along a plurality of sides (two opposite sides or four sides, for example) or one side of the optical chip 10.

The interconnect board 30 includes a base board 32 and an interconnecting pattern 34 formed on the base board 32. The base board 32 may be a film (flexible base board) used for Chip On Film (COF) mounting or tape automated bonding (TAB) mounting. The base board 32 may be a rigid base board.

The interconnecting pattern 34 may be formed on either one surface or each surface of the base board 32. The interconnecting pattern 34 may be formed by applying conventional technology such as plating technology or exposure technology. The interconnecting pattern 34 is formed by a plurality of interconnects and includes a plurality of terminals which serve as electrical connection sections. The terminal may be a land. As shown in FIG. 1, the electrode 24 of the optical chip 10 is electrically connected with the terminal of the interconnecting pattern 34.

In the present embodiment, an opening 36 is formed in the base board 32. The opening 36 is a through-hole in the base board 32, and may be formed larger than the external shape of the optical section 12.

As shown in FIG. 1, the optical chip 10 is bonded face down to the interconnect board 30. In more detail, the surface of the optical chip 10 on which the electrode 24 is formed faces the interconnect board 30. The optical section 12 is disposed to overlap the opening 36, specifically, to face the opening 36. This enables an optical path of the optical section 12 to be secured from the side of the interconnect board 30. Terminals of the interconnecting pattern 34 are disposed to surround the opening 36 corresponding to the electrodes 24 of the optical chip 10. The opening 36 may be covered with the optical chip 10. The electrodes 24 may be electrically connected with the interconnecting pattern 34 by allowing conductive particles to be interposed between the electrodes 24 and the interconnecting pattern 34 using an anisotropic conductive material 26 such as an anisotropic conductive film (ACF) or an anisotropic conductive paste (ACP). The anisotropic conductive material 26 is provided so as not to cover the optical section 12. The electrodes 24 may be electrically connected with the interconnecting pattern 34 by using a metal junction of a material such as Au—Au, Au—Sn, or solder.

The optical module may include an electronic part other than the optical chip 10 differing from the example shown in FIG. 1. The electronic part is mounted on the interconnect board 30 and electrically connected with the terminals of the interconnecting pattern 34. The electronic part is a part used to process electrical signals of the optical module. As examples of the electronic part, an active part (integrated circuit chip, for example) or a passive part (resistor or capacitor, for example) can be given.

The body material 40 holds a lens 42 for concentrating light on the optical section 12. The body material 40 covers the optical chip 10 (at least the optical section 12), and may be called a frame. The lens 42 is provided above the optical section 12. The lens 42 may be removable from the body material 40. In the case where the body material 40 and the lens 42 are used for imaging, the body material 40 and the lens 42 may be called an imaging optical system. The body material 40 may be formed of materials which can be separated, or integrally formed of one material.

In the example shown in FIG. 1, the body material 40 includes first and second sections 44 and 46. The lens 42 is installed in the first section 44. Specifically, the first section 44 is a lens holder. In more detail, the first section 44 includes a first hole 48 and holds the lens 42 in the first hole 48. The lens 42 may be secured in the first hole 48 by using a pressure structure (not shown) including a pressure tool which can move the lens 42 in the axial direction of the first hole 48 using a thread (not shown) formed in the first section 44. The lens 42 is held at an interval from the optical section 12 of the optical chip 10.

As shown in FIG. 1, the second section 46 includes a second hole 50 and holds the first section 44 in the second hole 50. The first and second holes 48 and 50 are connected to form one through-hole. First and second threads 52 and 54 are respectively formed outside the first section 44 and inside the second hole 50 of the second section 46. The first and second sections 44 and 46 are connected by these threads. The location of the first section 44 can be adjusted along the axial direction of the second hole 50 of the second section 46 by the first and second threads 52 and 54. The focus of the lens 42 can be adjusted in this manner. An optical filter 56 may be provided above the optical section 12. The optical filter 56 is provided between the optical section 12 and the lens 42. As shown in FIG. 1, the optical filter 56 may be provided in the second hole 50. The optical filter 56 may change optical loss depending on the wavelength, and transmit only light having a specific wavelength.

The body material 40 is directly attached to the optical chip 10. As the attachment means, an adhesive material may be used. The “body material 40 is directly attached to the optical chip 10” includes the case where the material used as the attachment means (adhesive material, for example) is present between the optical chip 10 and the body material 40. The “body material 40 is directly attached to the optical chip 10” includes the case where the body material 40 is attached to the optical chip 10 while being in contact with the optical chip 10. In the example shown in FIG. 1, the body material 40 is bonded to the optical chip 10 through a sheet material 60 (double-sided tape, for example) having adhesion. Since the sheet material 60 has a predetermined shape, flatness of the body material 40 is rarely impaired. The body material 40 may be bonded to the optical chip by using a liquid adhesive.

The body material 40 is attached to the optical chip 10 in the region excluding the electrodes 24. The body material 40 may be attached to the passivation film 16 of the optical chip 10. The body material 40 is attached in the region excluding the optical section 12 as described later.

In the present embodiment, the body material 40 is attached to the optical chip 10 while passing through the inside of the opening 36. At least a part of the body material 40 is located in the opening 36. Specifically, the body material 40 is attached to the optical chip 10 in the region exposed from the opening 36. In this case, the body material 40 is attached in the region excluding the optical section 12. In other words, the body material 40 is attached in the region which surrounds the optical section 12 so as to avoid the top of the optical section 12. In the example shown in FIG. 1, the body material 40 is attached to the surface of the optical chip 10 in the region outside the optical section 12 and inside the electrodes 24. The size and thickness of the optical module can be reduced, since the body material 40 is attached inside the opening 36 and the thickness of the interconnect board 30 does not affect the size of the optical module.

As shown in FIG. 1, the open end of the second hole 50 of the second section 46 of the body material 40 may be an attachment section 58 for the optical chip 10. The attachment section 58 may project in the direction of the optical chip 10 so that other sections of the body material 40 are held at an interval from the interconnect board 30. This enables the degree of flatness of the body material 40 to be adjusted based merely on the optical chip 10 as a reference. The planar shape of the attachment section 58 may be formed in the shape of a frame (ring) so as to enclose the optical section 12. This enables the optical section 12 to be covered with the body material 40, whereby incidence of unnecessary light on the optical section 12 can be eliminated.

A resin section 62 may be provided between the body material 40 and the interconnect board 30. The resin section 62 bonds the body material 40 to the interconnect board 30. The optical chip 10, the body material 40, and the interconnect board 30 can be secured relatively by providing the resin section 62.

In the optical module according to the present embodiment, the body material 40 is directly attached to the optical chip 10. This enables the optical chip 10 to mount on the body material 40 in a flat manner, whereby the optical axes of the optical section 12 and the lens 42 can be allowed to coincide accurately. Therefore, an optical module having high reliability and high quality (high image quality, for example) can be provided.

A method of manufacturing the optical module according to the present invention is described below. First, the optical chip 10 is mounted on the interconnect board 30. In more detail, the optical chip 10 is bonded face down to the interconnect board 30 at a location at which the optical section 12 overlaps (faces) the opening 36. The electrical connection between the electrodes 24 and the interconnecting pattern 34 is described above in detail.

The body material 40 is directly attached to the optical chip 10. The body material 40 may be bonded to the optical chip 10 through the adhesive sheet material 60. The body material 40 is disposed inside the opening 36. In this case, it is preferable to specify the planar location (location in the vertical and horizontal directions and the rotational (X, Y, θ) directions) while recognizing alignment marks. The alignment marks may be formed on either the optical chip 10 or the interconnect board 30.

The resin section 62 may be provided between the body material 40 and the interconnect board 30, if necessary, after the step of attaching the body material 40. The resin section 62 is formed by injecting a resin having flowability into the gap between the body material 40 and the interconnect board 30. The resin section 62 may be an adhesive material. Other items and effects of the method of manufacturing the optical module according to the present embodiment can be derived from the description of the optical module. Therefore, description of these is omitted.

### Second Embodiment

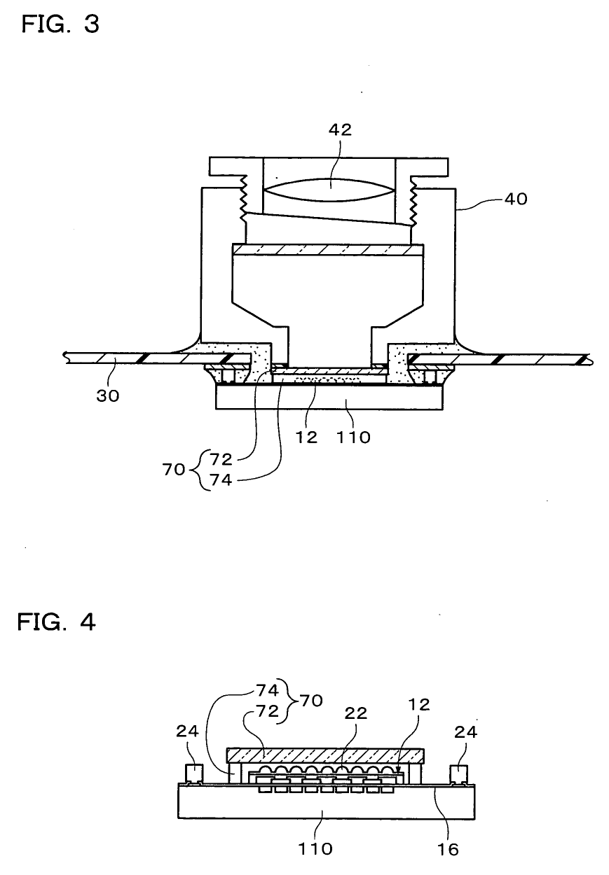

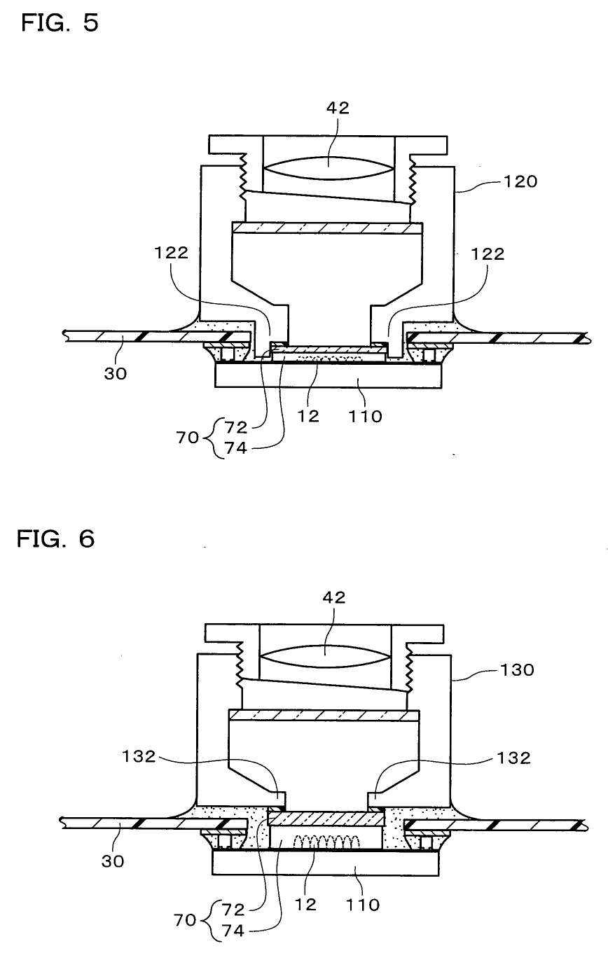

FIGS. 3 to 6 are views illustrating an optical module and a method of manufacturing the same according to a second embodiment of the present invention. FIG. 3 is a cross-sectional view of an optical module, FIG. 4 is a cross-sectional view of an optical chip, and FIGS. 5 and 6 are cross-sectional views of optical modules according to modifications. In the present embodiment, the optical module includes an optical chip 110, the interconnect board 30, and the body material 40. The description in the first embodiment can be applied to the interconnect board 30 and the body material 40.

The optical chip 110 according to the present embodiment includes a cover 70 provided to cover the optical section 12. The cover 70 includes a region which faces the optical section 12 at the center, and a region which does not face the optical section 12 at the end. The cover 70 has optical transparency at least in the region which faces the optical section 12 so that the optical path of the optical section 12 can be secured. The cover 70 is a base board, for example. The surface of the cover 70 is flat. The cover 70 is formed to avoid the electrodes 24. Refuse or an adhesive material can be prevented from entering the optical section 12 by providing the cover 70. The cover 70 may seal the optical section 12. The step of forming the cover 70 may be performed before the step of mounting the optical chip 10.

As shown in FIG. 4, the cover 70 includes a plate section 72 and a spacer section 74. The plate section 72 is disposed above the optical section 12 and has optical transparency. As the plate section 72, optical glass or optically transparent plastic may be used. The surface of the plate section 72 is flat. The amount of optical loss of the plate section 72 is not limited insofar as the plate section 72 transmits light. However, the plate section 72 preferably has high transmittance and low optical loss. The plate section 72 may transmit only light having a specific wavelength. For example, the plate section 72 may allow visible rays to pass therethrough, but may not allow light in the infrared region to pass therethrough. A material having a small loss for visible rays and a large loss for light in the infrared region may be used for the plate section 72. The surface of the plate section 72 may be subjected to optical processing (formation of a specific film, for example).

The spacer section 74 supports the plate section 72. The spacer section 74 is formed on the passivation film 16. The spacer section 74 is continuously formed to enclose the optical section 12. Specifically, the planar shape of the spacer section 74 is formed in the shape of a frame (ring) so as to enclose the optical section 12. The spacer section 74 may be formed by using a resin (thermosetting resin or photocurable resin, for example). In this case, the plate section 72 may be directly bonded to the spacer section 74. The spacer section 74 may be formed by using a metal. In this case, the plate section 72 may be secured through the spacer section 74 which contains a filler metal or an adhesive material.

In the example shown in FIG. 1, the plate section 72 and the spacer section 74 are separately formed. As modification, the plate section 72 and the spacer section 74 may be integrally formed. For example, the plate section 72 and the spacer section 74 may be integrally formed by injection molding of a resin.

As another modification, the spacer section 74 may be a layer which is provided between the optical section 12 and the plate section 72 and seals the optical section by adhering to the optical section. Specifically, the spacer section 74 is formed to cover the microlens array 22. As the spacer section 74, a resin (thermoplastic resin, for example) may be used. If the microlens array 22 consists of convex lenses as shown in FIG. 4, the absolute refractive index of the spacer section 74 is preferably smaller than the absolute refractive index of the microlens array 22. If the microlens array 22 consists of concave lenses, the absolute refractive index of the spacer section 74 is preferably greater than the absolute refractive index of the microlens array 22.

In the present embodiment, the body material 40 is attached to the cover 70 in the region except the optical section 12. In more detail, the body material 40 is attached to the end (end of the upper surface in more detail) of the cover 70. Since the surface of the cover 70 is flat, the degree of flatness of the body material 40 with respect to the optical chip 10 is easily acquired. In the example shown in FIG. 3, the body material 40 is attached to the plate section 72. The description of the first embodiment applies to other items and effects.

As shown in the modification of FIG. 5, a body material 120 may hold the corner of the cover 70. In more detail, an L-shaped groove may be formed in an attachment section 122 of the body material 120, and the body material 120 may be attached to the upper surface and the side surface of the cover 70 (plate section 72 in more detail). This facilitates alignment of the body material 120 and the optical chip 110.

As shown in the modification of FIG. 6, in the case where the cover 70 projects from the surface of the interconnect board 30, an attachment section 132 may be a part of a flat portion of a body material 130.

### Third Embodiment

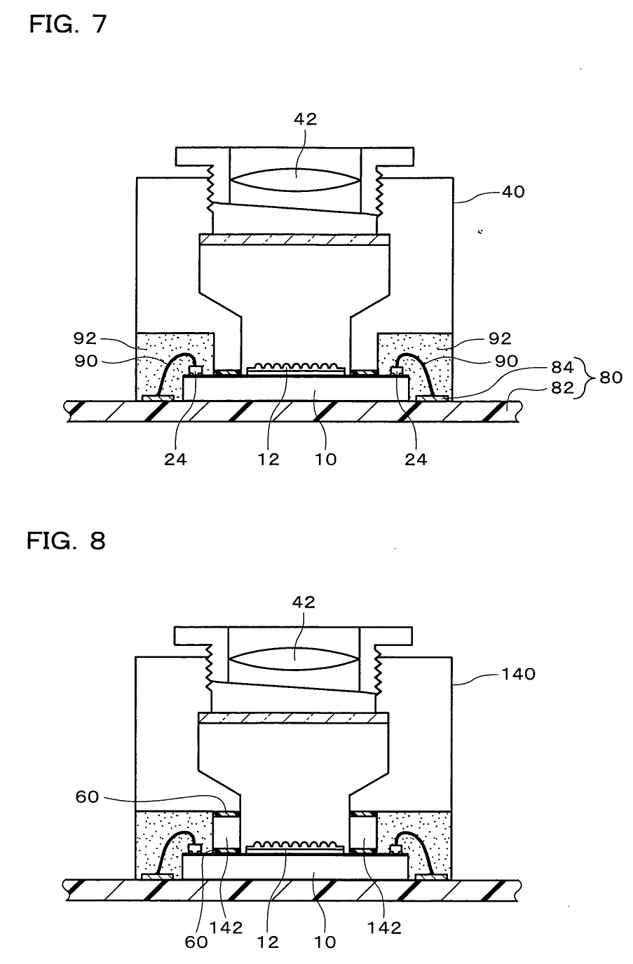

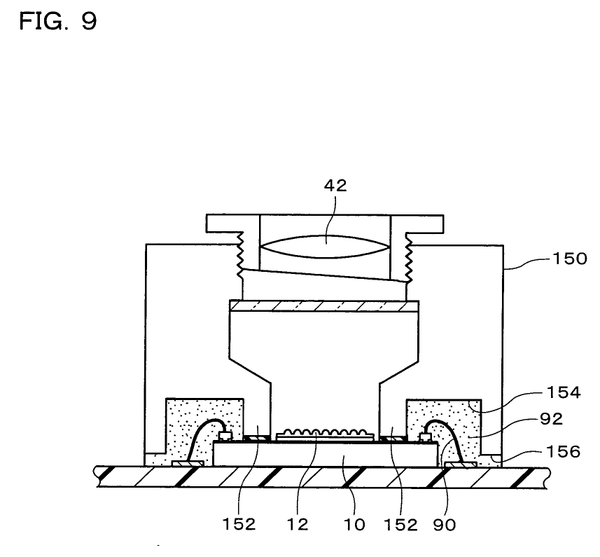

FIGS. 7 to 9 are views illustrating an optical module and a method of manufacturing the same according to a third embodiment of the present invention. FIG. 7 is a cross-sectional view of an optical module, and FIGS. 8 and 9 are cross-sectional views of optical modules according to modifications. In the present embodiment, the optical module includes the optical chip 10, an interconnect board 80, and the body material 40. The optical chip 10 is bonded face up to the interconnect board 80. The interconnect board 80 includes a base board 82 and an interconnecting pattern 84 formed on the base board 82. The description of the first embodiment can be applied to the interconnect board 80 except that the opening is not formed.

As shown in FIG. 7, the surface of the optical chip 10 on which the electrodes 24 are formed faces in the direction opposite to the interconnect board 80. The optical section 12 is disposed on the opposite side of the interconnect board 80. A plurality of terminals of the interconnecting pattern 84 are disposed to surround the optical chip 10. The electrodes 24 may be electrically connected with the interconnecting pattern 84 by using wires 90.

The body material 40 is disposed at a location higher than the optical chip 10 on the interconnect board 80. The description of the first embodiment can be applied to the attachment of the body material 40. A resin section 92 may be provided between the body material 40 and the interconnect board 80. The resin section 92 bonds the body material 40 to the interconnect board 30. The optical chip 10, the body material 40, and the interconnect board 80 can be secured relatively by providing the resin section 92. In the example shown in FIG. 7, the resin section 92 seals at least the wires 90. In more detail, the resin section 92 seals the electrical connection sections such as the electrodes 24, the wires 90, and the terminals of the interconnecting pattern 84. The resin section 92 may be provided in advance to the interconnect board 80 before the step of attaching the body material 40, or may be provided between the body material 40 and the interconnect board 80 after the step of attaching the body material 40. The description of the first or second embodiment applies to other items and effects.

As shown in the modification of FIG. 8, an attachment section 142 of a body material 140 may be formed so that the attachment section 142 can be separated from a body section having the lens. For example, the attachment section 142 in the shape of a frame (ring) which encloses the optical section 12 is directly attached to the optical chip 10, and the body section of the body material 140 is secured to the attachment section 142. The body section may be bonded to the attachment section 142 through the adhesive sheet material 60. According to this modification, since the body material 140 is set in several steps, the steps can be performed while confirming the degree of flatness of the body material 140.

As shown in the modification of FIG. 9, a space 154 provided outside an attachment section 152 and a hole 156 which opens to the outside from the space 154 may be formed in a body material 150. At least the space 154 (space 154 and hole 156 in FIG. 9) is filled with the resin section 92. The space 154 has a shape so as to surround the wires 90. For example, the space 154 may be formed along the arrangement of the electrodes 24 so as to surround the wires 90. The space 154 may be integrally formed to surround all the wires 90 of the optical chip 10. The space 154 may be formed in the shape of a frame (ring) outside the attachment section 152. The hole 156 has a width smaller than that of the space 154. The hole 156 forms a passage for the material for the resin section 92 to the space 154. The form of the hole 156 is not limited. According to this modification, since the step of forming the resin section 92 is facilitated, the step of sealing the wires 90 and the step of bonding and securing the body material 40 and the interconnect board 30 are facilitated.

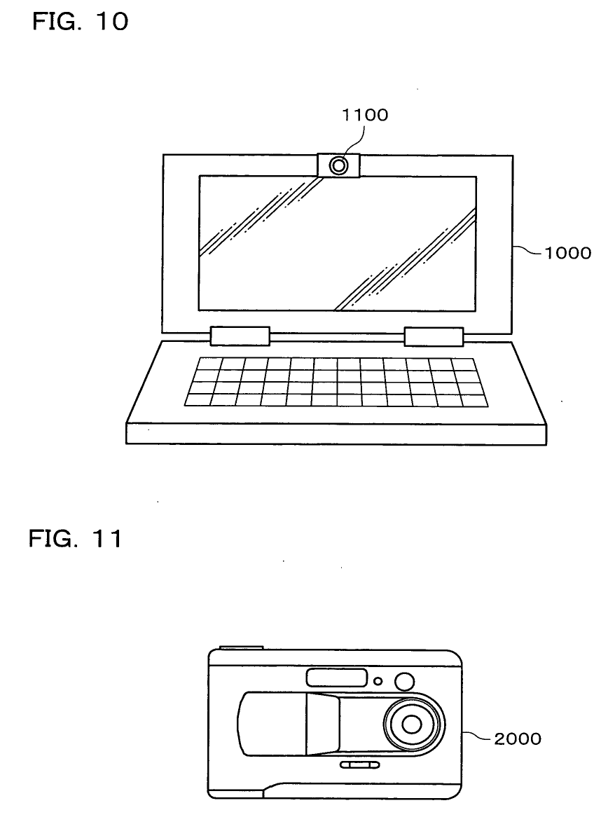

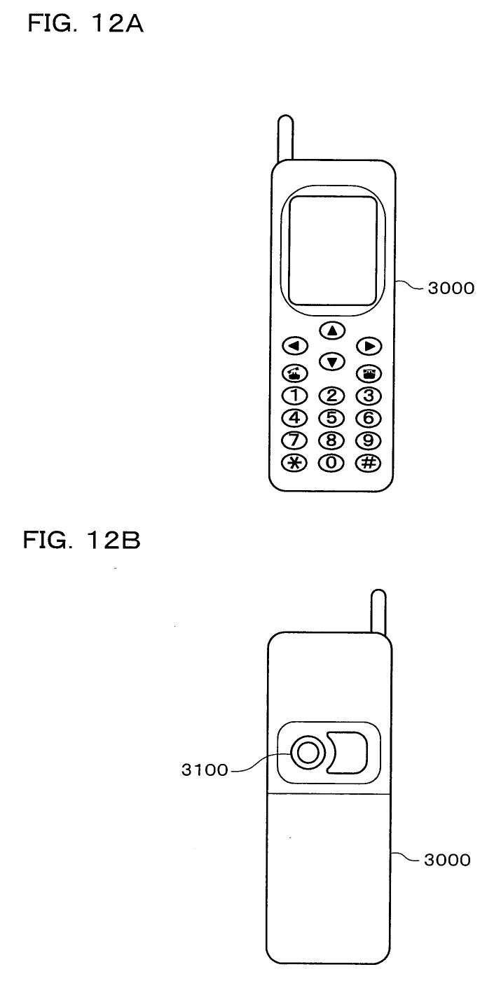

A notebook type personal computer 1000 shown in FIG. 10 as an electronic instrument according to an embodiment of the present invention includes a camera 1100 in which an optical module is incorporated. A digital camera 2000 shown in FIG. 11 includes an optical module. A portable telephone 3000 shown in FIGS. 12A and 12B includes a camera 3100 in which an optical module is incorporated.

The present invention is not limited to the above-described embodiments. Various modifications and variations are possible. For example, the present invention includes configurations essentially the same as the configurations described in the embodiments (for example, configurations having the same function, method, and results, or configurations having the same object and results). The present invention includes configurations in which any unessential part of the configuration described in the embodiments is replaced. The present invention includes configurations having the same effects or achieving the same object as the configurations described in the embodiments. The present invention includes configurations in which conventional technology is added to the configurations described in the embodiments.

What is claimed is:

1. An optical module comprising:
an interconnect board which includes a base board and an interconnecting pattern formed on the base board;
an optical chip which includes an optical section and an electrode which electrically connects the optical section and the interconnecting pattern; and
a body material which holds a lens which concentrates light on the optical section,
wherein the body material is directly attached to the optical chip.

2. The optical module as defined in claim 1,
wherein an opening is formed in the base board,
wherein the optical chip is bonded face down to the interconnect board so that the optical section faces the opening, and
wherein the body material is attached to the optical chip through the opening.

3. The optical module as defined in claim 1, wherein the body material is attached to a surface of the optical chip on which the optical section is formed.

4. The optical module as defined in claim 1, further comprising a resin section which is provided between the body material and the interconnect board to bond the body material to the interconnect board.

5. The optical module as defined in claim 4,
wherein the optical chip is bonded face up to the interconnect board,
wherein the electrode and the interconnecting pattern are electrically connected through a wire, and
wherein the resin section seals at least the wire.

6. The optical module as defined in claim 5,
wherein a space having a shape which surrounds the wire, and a hole which has a width smaller than a width of the space and opens to an outside from the space are formed in the body material, and
wherein the space is filled with the resin section.

7. The optical module as defined in claim 1, wherein the body material is attached to the optical chip in a region except the optical section.

8. The optical module as defined in claim 1,
wherein the optical chip further includes a cover provided to cover the optical section, and
wherein the body material is attached to the cover.

9. The optical module as defined in claim 1,
wherein the cover includes a plate section disposed above the optical section, and a spacer section which supports the plate section,
wherein the spacer section is attached to the optical chip, and
wherein the body material is attached to the plate section.

10. The optical module as defined in claim 1, wherein the body material is bonded to the optical chip through an adhesive sheet material.

11. The optical module as defined in claim 1, wherein the body material is bonded to the optical chip through an adhesive.

12. An electronic instrument comprising the optical module as defined in claim 1.

13. A method of manufacturing an optical module comprising:
mounting an optical chip which includes an optical section and an electrode on an interconnect board which includes a base board and an interconnecting pattern formed on the base board so that the electrode is electrically connected with the interconnecting pattern; and
directly attaching a body material which holds a lens which concentrates light on the optical section to the optical chip.
